(19) United States
(12) Patent Application Publication
(10) Pub. No.: US 2020/0236806 A1
(43) Pub. Date: Jul. 23, 2020

(54) HEAT SINK WITH INTERNAL CHAMBER FOR PHASE CHANGE MATERIAL

(71) Applicant: UNITED ARAB EMIRATES UNIVERSITY, AL-AIN (AE)

(72) Inventor: SALAH ADDIN BURHAN AL OMARI, AL AIN (AE)

(21) Appl. No.: 16/251,748

(22) Filed: Jan. 18, 2019

(51) Int. Cl. H05K 7/20; F28D 21/00

(52) U.S. Cl. CPC H05K 7/20327; F28D 21/00; F28D 2021/0029; H05K 7/20318; H05K 7/20309

(57) ABSTRACT

The heat sink with internal chamber for phase change material is formed from a body of solid phase change material received within a thermally conductive housing such that at least one contact face of the body of solid phase change material is exposed for direct contact with a heat source to be cooled. A quantity of at least one liquid phase change material at least partially fills at least one chamber formed within the body of solid phase change material. The first end of at least one tube is in open fluid communication with the at least one chamber formed within the body of solid phase change material. The at least one tube at least partially projects through and outside of the body of solid phase change material and the thermally conductive housing, and may loop back into the chamber.

### BACKGROUND

### 1. Field

The disclosure of the present patent application relates to heat sinks, and particularly to a heat sink with an internal chamber for phase change material.

### 2. Description of the Related Art

As electronic technology continues to advance, electronic components, such as processor chips, are being made to provide faster operational speeds and greater functional capabilities. When a typical processor chip or a similar integrated circuit or modular circuit package operates at a high speed inside a computer or device housing, its temperature increases at a rapid rate. It is therefore necessary to dissipate the generated heat before any damage to the system may occur.

Conventionally, a heat sink is used to dissipate heat generated by a processor or the like. A conventional heat sink includes a base, which makes direct contact with the heat source, and a plurality of cooling fins. The heat sink dissipates heat by conduction through the base and into the fins, followed by convective cooling of the fins. However, as the power of electronic devices increases, so does the heat generated by their internal components, thus requiring heat sinks that are capable of dissipating heat far more effectively. For this reason, phase change material-type heat sinks have gradually begun to replace conventional heat sinks.

A typical phase change material-type heat sink has an evacuated cavity with a volume of working fluid sealed within the cavity. The phase change material-type heat sink transfers heat via phase transition of the working fluid. Thus, the phase change material-type heat sink has good heat conductivity and can quickly transfer heat from one place to another place. A typical phase change material heat sink may include a hermetically sealed container with a volume of water enclosed therein. The container is typically vacuum-exhausted, thus enhancing the evaporative effect of the water. The container includes a base for contacting the heat source, and a cover facing the base, typically with a plurality of cooling fins attached thereto. In use, heat produced by the heat source is conducted to the base, and this heat evaporates the water. The water vapor flows toward the cover and dissipates the heat thereto. This heat exchange condenses the water back into the liquid phase, which falls back toward the base, under the force of gravity, to continue the cycle. The heat transferred to the cover is radiated by the fins to the surrounding air.

Although such a phase change material-type heat sink is more efficient than a conventional heat sink, a typical water-based phase change material-type heat sink, as described above, is still limited in its effectiveness, primarily due to design considerations, such as thermal conductivity and heat capacity of the materials involved as functions of the physical dimensions of the heat sink. Thus, a heat sink with an internal chamber for phase change material solving the aforementioned problems is desired.

### SUMMARY

In one embodiment, the present subject matter is directed to a heat sink with internal chamber for phase change material. In an embodiment, the heat sink is formed from a body of solid phase change material, with at least one additional liquid phase change material disposed in an internal chamber defined within the body of solid phase change material. The body of solid phase change material is received within a thermally conductive housing such that at least one contact face of the body of solid phase change material is exposed, allowing for direct contact with a heat source requiring cooling. The volume of the at least one liquid phase change material at least partially fills at least one internal chamber formed within the body of solid phase change material.

The first end of at least one tube is in open fluid communication with the at least one internal chamber formed within the body of the solid phase change material. The at least one tube at least partially projects through and outside of the body of the solid phase change material and the thermally conductive housing, and may have a plurality of thermally conductive fins mounted to at least a portion thereof. The thermally conductive fins may be mounted outside the body of the solid phase change material and the thermally conductive housing, inside the body of the solid phase change material, or both. In use, heat generated by the heat source is transferred, via conduction, into the body of the solid phase change material. In addition to the heat transferred into the solid phase change material, the heat can further be transferred into the at least one liquid phase change material contained within the at least one internal chamber. The heat causes some portion of the at least one liquid phase change material in the at least one internal chamber to evaporate, and the vapor flows into the at least one tube, where the vapor is cooled through heat exchange with the ambient environment. The cooling of the vapor condenses the evaporated liquid phase change material back into its liquid state, and the at least one liquid phase change material drips, under the force of gravity, back into the at least one internal chamber for reuse, thereby aiding in cooling the heat source. The heat from the heat source may also cause at least a portion of the body of solid phase change material to convert into a liquid. The body of solid phase change material will thus absorb and store additional heat until it can be transferred to the at least one liquid phase change material, cooling the solid phase change material and allowing the portion thereof converted to a liquid to return to a solid state.

In another embodiment, the heat sink is formed from a body of solid phase change material, with at least one liquid phase change material disposed in a plurality of internal chambers defined within the body of solid phase change material. The body of solid phase change material is received within a thermally conductive housing such that at least one contact face of the body of solid phase change material is exposed, allowing for direct contact with a heat source requiring cooling. The volume of the at least one liquid phase change material at least partially fills at least one internal chamber formed within the body of solid phase change material. The plurality of internal chambers can be connected by one or more fluid passages.

The first end of at least one tube is in open fluid communication with at least one of the internal chambers formed within the body of the solid phase change material. The at least one tube at least partially projects through and outside of the body of the solid phase change material and the thermally conductive housing, and may have a plurality of thermally conductive fins mounted to at least a portion thereof. The thermally conductive fins may be mounted outside the body of the solid phase change material and the thermally conductive housing, inside the body of the solid phase change material, or both. In use, heat generated by the heat source is transferred, via conduction, into the body of the solid phase change material. In addition to the heat transferred into the solid phase change material, the heat can further be transferred into the at least one liquid phase change material contained within the at least one internal chamber. The heat causes some portion of the at least one liquid phase change material in the at least one internal chamber to evaporate, and the vapor flows into the at least one tube, where the vapor is cooled through heat exchange with the ambient environment. The cooling of the vapor condenses the evaporated liquid phase change material back into its liquid state, and the at least one liquid phase change material drips, under the force of gravity, back into the at least one internal chamber for reuse, thereby aiding in cooling the heat source. The heat from the heat source may also cause at least a portion of the body of solid phase change material to convert into a liquid. The body of solid phase change material will thus absorb and store additional heat until it can be transferred to the at least one liquid phase change material, cooling the solid phase change material and allowing the portion thereof converted to a liquid to return to a solid state. The fluid passages, when present, provide open fluid communication between the plurality of internal chambers, allowing the at least one liquid phase change material to flow from an internal chamber absorbing less heat to an internal chamber absorbing more heat.

These and other features of the present disclosure will become readily apparent upon further review of the following specification and drawings.

### BRIEF DESCRIPTION OF THE DRAWINGS

FIG. 1 is a side view in section of a heat sink with internal chamber for phase change material.

FIG. 2 is a side view in section of an alternative embodiment of a heat sink with internal chamber for phase change material having a thermally conductive component within the internal chamber.

FIG. 3 is a side view in section of another alternative embodiment of a heat sink with internal chamber for phase change material having at least one tube in open fluid communication with the internal chamber at a first end and a second end.

FIG. 4 is a side view in section of still another alternative embodiment of a heat sink with at least two internal chambers for phase change material having at least a solid phase change material and a liquid phase change material within the internal chambers.

FIG. 5 is a side view in section of yet another alternative embodiment of a heat sink with internal chamber for phase change material having at least one tube that exits the internal chamber and returns, passing through the multiple phase change materials within the internal chamber.

FIG. 6 is a side view in section of an alternative embodiment of a heat sink with internal chamber for phase change material having at least two internal chambers in open fluid communication.

FIG. 7 is a side view in section of an alternative embodiment of a heat sink with internal chamber for phase change material having at least two internal chambers in open fluid communication with each other and having at least a solid phase change material and a liquid phase change material within each of the at least two internal chambers.

FIG. 8 is a side view in section of still another alternative embodiment of a heat sink with internal chamber for phase change material having at least one internal chamber containing a liquid phase change material and at least one internal chamber containing at least a solid phase change material.

FIG. 9 is a side view in section of yet another alternative embodiment of a heat sink with internal chamber for phase change material having at least one tube that passes through a passage formed through the heat source as it transits the body of solid phase change material.

FIG. 10A is a side view in section of an alternative embodiment of a heat sink with internal chamber for phase change material having at least one internal chamber containing a liquid phase change material and further containing at least one encapsulated phase change material.

FIG. 10B is a side view in section of an alternative embodiment of a heat sink with internal chamber for phase change material having at least one internal chamber containing a liquid phase change material, further containing at least one encapsulated phase change material, with at least one tube in open fluid communication with the at least one internal chamber.

FIG. 11 is a side view in section of another alternative embodiment of a heat sink with at least one helical internal chamber containing phase change material therein.

FIG. 12 is a side view in section of still another alternative embodiment of a heat sink with internal chamber for phase change material having multiple sub-chambers in open fluid communication.

Similar reference characters denote corresponding features consistently throughout the attached drawings.

### DETAILED DESCRIPTION OF THE PREFERRED EMBODIMENTS

In one embodiment, the present subject matter is directed to a heat sink with internal chamber for phase change material. In an embodiment, the heat sink is formed from a body of solid phase change material, with at least one additional liquid phase change material disposed in at least one internal chamber defined within the body of solid phase change material. The body of solid phase change material is received within a thermally conductive housing such that at least one contact face of the body of solid phase change material is exposed, allowing for direct contact with a heat source requiring cooling. The volume of the at least one liquid phase change material at least partially fills the at least one internal chamber formed within the body of solid phase change material.

The first end of at least one tube is in open fluid communication with the at least one internal chamber formed within the body of the solid phase change material. The at least one tube at least partially projects through and outside of the body of the solid phase change material and the thermally conductive housing, and may have a plurality of thermally conductive fins mounted to at least a portion thereof. The thermally conductive fins may be mounted outside the body of the solid phase change material and the thermally conductive housing, inside the body of the solid phase change material, or both.

In use, heat generated by the heat source is transferred, via conduction, into the body of the solid phase change material. In addition to the heat transferred into the solid phase change material, the heat can further be transferred into the at least one liquid phase change material contained within the at least one internal chamber. The heat causes some portion of the at least one liquid phase change material in the at least one internal chamber to evaporate, and the vapor flows into the at least one tube, where the vapor is cooled through heat exchange with the ambient environment. The cooling of the vapor condenses the evaporated liquid phase change material back into its liquid state, and the at least one liquid phase change material drips, under the force of gravity, back into the at least one internal chamber for reuse, thereby aiding in cooling the heat source. The heat from the heat source may also cause at least a portion of the body of solid phase change material to convert into a liquid. The solid phase change material will thus absorb and store additional heat until it can be transferred to the at least one liquid phase change material, cooling the solid phase change material and allowing the portion thereof converted to a liquid to return to a solid state.

In some embodiments, the body of solid phase change material may be selected to be in a liquid state under operating conditions. In these embodiments, the solid phase change material selected to form the body of solid phase change material may have particularly high thermal conductivity, such as liquid gallium. In these embodiments, the body of solid phase change material having high thermal conductivity and being in the liquid phase will rapidly distribute heat from the heat source to the at least one internal chamber and to the at least one liquid phase change material contained therein. In these embodiments, the presence of the at least one internal chamber and the at least one liquid phase change material will assist in overcoming the low specific heat capacity of the liquid phase body of solid phase change material.

In an alternative embodiment, the heat sink with internal chamber for phase change material may be used as a heat source for a boiler of a steam power plant. In this embodiment, the heat sink may also be used to cool a concentrated solar collector, effectively transferring the heat generated by the concentrated solar collector to the boiler of the steam power plant. In this embodiment, the body of solid phase change material may be selected to have a particularly high conductivity and a particularly high boiling temperature, such as liquid gallium (boiling temperature above 2,000° C.). In this embodiment the at least one internal chamber containing at least one liquid phase change material may act as the water drum in the steam power plant.

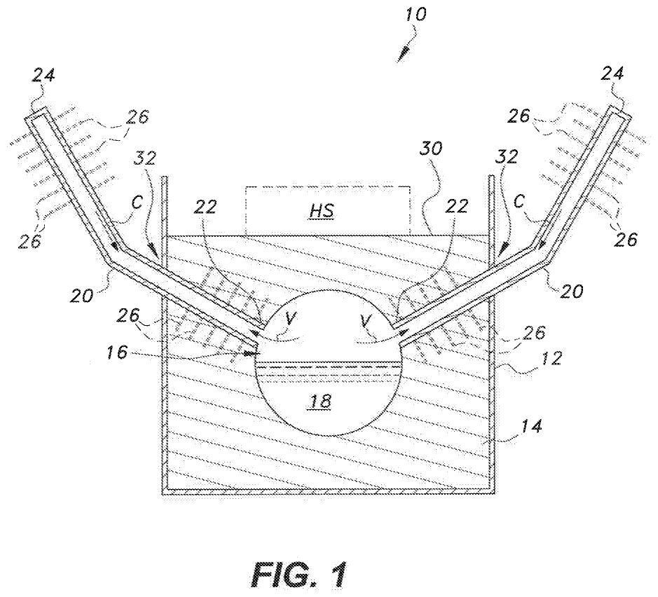

Referring to FIG. 1, the heat sink with internal chamber for phase change material, designated generally as 10, is a heat sink formed from a body of solid phase change material 14, with at least one liquid phase change material 18 disposed in an internal chamber 16 defined within the body of solid phase change material 14. As shown, the body of solid phase change material 14 is disposed within a thermally conductive housing 12 such that at least one contact face 30 of the body of solid phase change material 14 is exposed, allowing for direct contact with a heat source HS that requires cooling. It should be understood that the heat source HS may be any component that requires cooling. In some embodiments, the component that requires cooling can be a processor chip, an integrated circuit chip, a modular circuit package, a photovoltaic cell, a light emitting diode, the exhaust duct of a combustion system or the like. In other embodiments, the heat sink with internal chamber for phase change material 10 can provide cooling, energy storage, and/or energy transfer, such as when cooling a solar collector, or generally when used in power generation or solar energy applications, and the like. It should be further understood that the overall configuration and relative dimensions of the housing 12, the body of solid phase change material 14 and the internal chamber 16 are shown for purposes of illustration only. It should further be understood that in use the body of solid phase change material 14 may be in a solid state, a partially melted state, or a liquid state.

The housing 12 may be selected from any suitable material that is compatible with the selected solid phase change material 14. For example, aluminum would not be used as a housing 12 material when the solid phase change material 14 selected is elemental gallium.

A quantity of the at least one liquid phase change material 18 at least partially fills at least one internal chamber 16 formed within the body of solid phase change material 14. Although only a single internal chamber 16 is shown in the example of FIG. 1, as will be described in greater detail below, a plurality of internal chambers may be formed within the body of solid phase change material 14. Additionally, it should be understood that the quantity of at least one liquid phase change material 18 shown in the internal chamber 16 is shown for exemplary purposes only, and is not intended to reflect an actual volumetric ratio of the at least one liquid phase change material 18 with respect to either the internal chamber 16 or the body of solid phase change material 14.

The first end 22 of the at least one tube 20 is in open fluid communication with the at least one internal chamber 16 formed within the body of solid phase change material 14. In the example of FIG. 1, two such tubes 20 are shown. However, as will be described in greater detail below, one or a plurality of such tubes may be provided. The at least one tube 20 at least partially projects through and outside of the body of solid phase change material 14 and the thermally conductive housing 12 (projecting through opening 32), and may have a plurality of thermally conductive fins 26. The thermally conductive fins 26 may be mounted outside the body of the solid phase change material 14 and the thermally conductive housing 12, inside the body of the solid phase change material 14, or both. In the embodiment of FIG. 1, the second end 24 of the at least one tube 20, which is opposed to the first end 22, is closed. It should be understood that the overall configuration and relative dimensions of the at least one tube 20 are shown for exemplary purposes only. Similarly, it should be understood that the positioning, overall configuration, relative dimensions, and number of thermally conductive fins 26 are also shown for exemplary purposes only. In an embodiment, the thermally conductive fins 26 are all on a portion of the at least one tube 20 outside of the body of solid phase change material 14 and the thermally conductive housing 12. In an embodiment, the thermally conductive fins 26 are all on a portion of the at least one tube 20 inside of the body of the solid phase change material 14 and the thermally conductive housing 12. In an embodiment, the thermally conductive fins 26 are on portions of the at least one tube 20 outside of the body of solid phase change material 14 and on a portion of the at least one tube inside of the body of solid phase change material 14.

The at least one liquid phase change material 18 is selected such that after forming a vapor V by exposure to heat from the heat source HS, the vapor V will condense back into a liquid when exposed, through the tube 20, to the conditions of the ambient environment within which the heat sink will be operating. The selection of the at least one liquid phase change material 18 may depend upon a number of conditions, including anticipated pressure in the at least one internal chamber 16 and external temperature during operation, and the surface area of the at least one tube. Under otherwise standard conditions, such as atmospheric temperature, the at least one liquid phase change material 18 will have a boiling point slightly above the temperature of the ambient environment. Where the at least one tube 20 has a larger surface area, the at least one liquid phase change material 18 may be selected to have a boiling point 1° to 5° C. above the temperature of the ambient environment. Where the at least one tube 20 has a smaller surface area, the at least one liquid phase change material 18 may be selected to have a boiling point 5° to 10° C. above the temperature of the ambient environment. Generally, the anticipated atmospheric temperature and the surface area of the at least one tube 20 will be the primary criteria used to select an appropriate at least one liquid phase change material 18. Multiple liquid phase change materials 18 having different boiling points within the desired range of operation may be mixed in the at least one internal chamber 16 in order to smooth the temperature range of phase change under varying ambient conditions. The pressure of the at least one internal chamber 16 may also be adjusted to optimize the boiling point of the selected liquid phase change material for a particular intended use. Non-limiting examples of liquid phase change materials 18 include one or more of water, formic acid, caprylic acid, glycerin, acetic acid, polyethylene glycol 600, n-hexadecane and n-heptadecane.

The phase change material for the body of solid phase change material 14 is selected such that it has a melting temperature between the operating temperature of the heat sink and the boiling temperature of the at least one liquid phase change material 18. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

In use, heat generated by the heat source HS is transferred, via conduction, into the body of solid phase change material 14. This may result in melting of at least a portion of the body of solid phase change material, absorbing some of the heat from the heat source. In addition to the heat transferred into the body of solid phase change material 14 and used in the melting thereof, the heat can further be transferred into the at least one liquid phase change material 18 contained within the at least one internal chamber 16. The heat causes the some portion of the at least one liquid phase change material 18 in the at least one internal chamber 16 to evaporate, and the vapor V flows into the at least one tube 20. As described above, in the embodiment of FIG. 1, the second end 24 of the at least one tube 20 is closed. The vapor V cools through heat exchange with the ambient environment (enhanced by cooling fins 26). The cooling of the vapor V condenses the at least one liquid phase change material 18 back into its liquid state, and the at least one liquid phase change material 18 drips by gravity back into the at least one internal chamber 16 for reuse. Thus the heat from the heat source HS is quickly and efficiently transferred to the ambient environment.

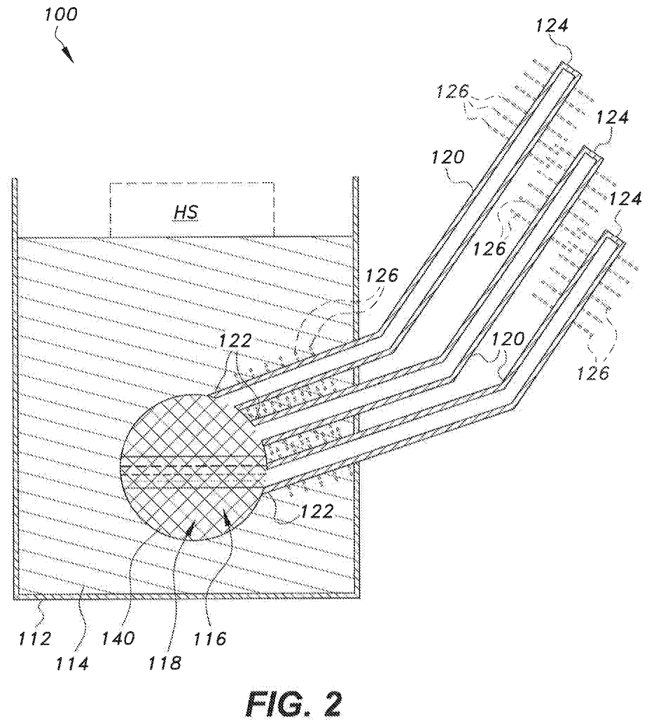

In the alternative embodiment of FIG. 2, the heat sink with internal chamber for phase change material, designated generally as 100, is also a heat sink formed from a body of solid phase change material 114, with at least one liquid phase change material 118 disposed in at least one internal chamber 116 defined within the body of solid phase change material 114. The body of solid phase change material 114 is again disposed within a thermally conductive housing 112 and is adapted for direct contact with a heat source HS. As in the previous embodiment, it should be understood that the overall configuration and relative dimensions of the housing 112, the body of solid phase change material 114, and the at least one internal chamber 116 are shown for purposes of illustration only.

A quantity of at least one liquid phase change material 118 at least partially fills at least one internal chamber 116 formed within the body of solid phase change material 114. In the embodiment of FIG. 2, the at least one liquid phase change material 118 is shown at least partially permeating a thermally conductive component 140, within the internal chamber 116. The thermally conductive component may be any suitable thermally conductive component, such as a thermally conductive foam, matrix, grid, mesh, or the like.

As noted above with regard to FIG. 1, a plurality of tubes 120 may be provided. In the example of FIG. 2, three such tubes 120 are shown, each having a first end 122, which is in open fluid communication with the at least one internal chamber 116 formed within the body of solid phase change material 114, and an opposed closed end 124. Each of the plurality of tubes 120 at least partially projects through and outside of the body of solid phase change material 114 and the thermally conductive housing 112, and may have a plurality of thermally conductive fins 126 mounted on at least a portion thereof. The thermally conductive fins 126 may be mounted outside the body of the solid phase change material 114 and the thermally conductive housing 112, inside the body of the solid phase change material 114, or both. It should be understood that the overall configuration and relative dimensions of each of the plurality of tubes 120 are shown for exemplary purposes only. Similarly, it should be understood that the positioning, overall configuration, relative dimensions and number of thermally conductive fins 126 are also shown for exemplary purposes only.

In the embodiment of FIG. 2, the thermally conductive component 140 may be selected to optimize heat transfer to the at least one liquid phase change material 118, and to optimize pore size to allow the at least one liquid phase change material 118 to escape to the plurality of tubes 120 once it has evaporated.

As in the previous embodiment, the at least one liquid phase change material 118 is selected such that after forming a vapor V by exposure to heat from the heat source HS, the vapor V will condense back into a liquid when exposed, through the plurality of tubes 120, to the conditions of the ambient environment within which the heat sink will be operating. The selection of the at least one liquid phase change material 118 may depend upon a number of conditions, including anticipated pressure in the at least one internal chamber 116 and external temperature during operation, and the surface area of the plurality of tubes 120. Under otherwise standard conditions, such as atmospheric temperature, the at least one liquid phase change material 118 will have a boiling point slightly above the temperature of the ambient environment. Where the plurality of tubes 120 has a larger surface area, the at least one liquid phase change material 118 will be selected to have a boiling point 1° to 5° C. above the temperature of the ambient environment. Where the plurality of tubes 120 has a smaller surface area, the at least one liquid phase change material 118 will be selected to have a boiling point 5° to 10° C. above the temperature of the ambient environment. Generally, the anticipated atmospheric temperature and the surface area of the plurality of tubes 120 will be the primary criteria used to select an appropriate at least one liquid phase change material 118. Multiple liquid phase change materials 118 having different boiling points within the desired range of operation may be mixed in the at least one internal chamber 116 in order to smooth the temperature range of phase change under varying ambient conditions. The pressure of the at least one internal chamber 116 may also be adjusted to optimize the boiling point of the selected liquid phase change material for a particular intended use. Non-limiting examples of liquid phase change materials 118 include one or more of water, formic acid, caprylic acid, glycerin, acetic acid, polyethylene glycol 600, n-hexadecane and n-heptadecane.

As in the previous embodiment, the phase change material for the body of solid phase change material 114 is selected such that it has a melting temperature between the operating temperature of the heat sink and the boiling temperature of the at least one liquid phase change material 118. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

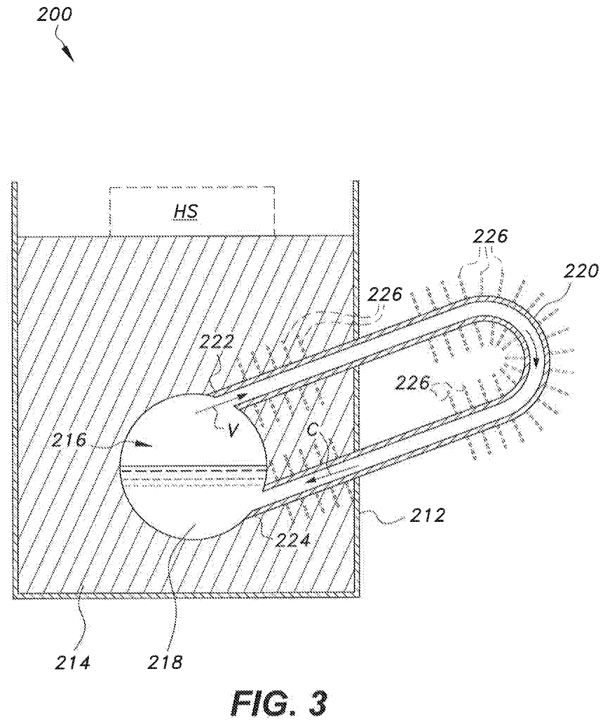

The heat sink with internal chamber for phase change material, designated generally as 200 in the alternative embodiment of FIG. 3, is similar to that of the previous embodiments, including a body of solid phase change material 214 with at least one liquid phase change material 218 disposed in at least one internal chamber 216 defined therein. The body of solid phase change material 214 is again disposed within a thermally conductive housing 212 and is adapted for direct contact with a heat source US. As in the previous embodiments, it should be understood that the overall configuration and relative dimensions of the housing 212, the body of solid phase change material 214, and the at least one internal chamber 216 are shown for purposes of illustration only.

Similar to the previous embodiments, a quantity of at least one liquid phase change material 218 at least partially fills the at least one internal chamber 216 formed within the body of solid phase change material 214.

The alternative embodiment of FIG. 3 includes at least one tube 220 having a first end 222 in open fluid communication with the at least one internal chamber 216 formed within the body of solid phase change material 214, and an opposed second end 224. However, as shown, the opposed second end 224 is also in fluid communication with the at least one internal chamber 216. Thus, in use, as the at least one liquid phase change material 218 evaporates, the vapor V flows through the at least one tube 220 and condenses, the condensate C flowing back down the at least one tube 220 toward the open second end 224 by gravity and rejoining the at least one liquid phase change material in the at least one internal chamber 216 for reuse. As in the previous embodiments, the at least one tube 220 at least partially projects through and outside of the body of solid phase change material 214 and the thermally conductive housing 212, and may have a plurality of thermally conductive fins 226 mounted on at least a portion thereof. The thermally conductive fins 226 may be mounted outside the body of the solid phase change material 214 and the thermally conductive housing 212, inside the body of the solid phase change material 214, or both. It should be understood that the overall configuration and relative dimensions of the at least one tube 220 are shown for exemplary purposes only. Similarly, it should be understood that the positioning, overall configuration, relative dimensions and number of thermally conductive fins 226 are also shown for exemplary purposes only.

As in the previous embodiment, the at least one liquid phase change material 218 is selected such that it will condense back into a liquid when exposed, through the at least one tube 220, to the conditions of the ambient environment within which the heat sink will be operating. The selection of the at least one liquid phase change material 218 may depend upon a number of conditions, including anticipated pressure in the at least one internal chamber 216 and external temperature during operation, and the surface area of the at least one tube. Under otherwise standard conditions, such as atmospheric temperature, the at least one liquid phase change material 218 will have a boiling point slightly above the temperature of the ambient environment. Where the at least one tube 220 has a larger surface area, the at least one liquid phase change material 218 will be selected to have a boiling point 1° to 5° C. above the temperature of the ambient environment. Where the at least one tube 220 has a smaller surface area, the at least one liquid phase change material 218 will be selected to have a boiling point 5° to 10° C. above the temperature of the ambient environment. Generally, the anticipated atmospheric temperature and the surface area of the at least one tube 220 will be the primary criteria used to select an appropriate at least one liquid phase change material 218. Multiple liquid phase change materials 218 having different boiling points within the desired range of operation may be mixed in the at least one internal chamber 216 in order to smooth the temperature range of phase change under varying ambient conditions. The pressure of the at least one internal chamber 216 may also be adjusted to optimize the boiling point of the selected liquid phase change material for a particular intended use. Non-limiting examples of liquid phase change materials 218 include one or more of water, formic acid, caprylic acid, glycerin, acetic acid, polyethylene glycol 600, n-hexadecane and n-heptadecane.

As in the previous embodiment, the phase change material for the body of solid phase change material 214 is selected such that it has a melting temperature between the operating temperature of the heat sink and the boiling temperature of the at least one liquid phase change material 218. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

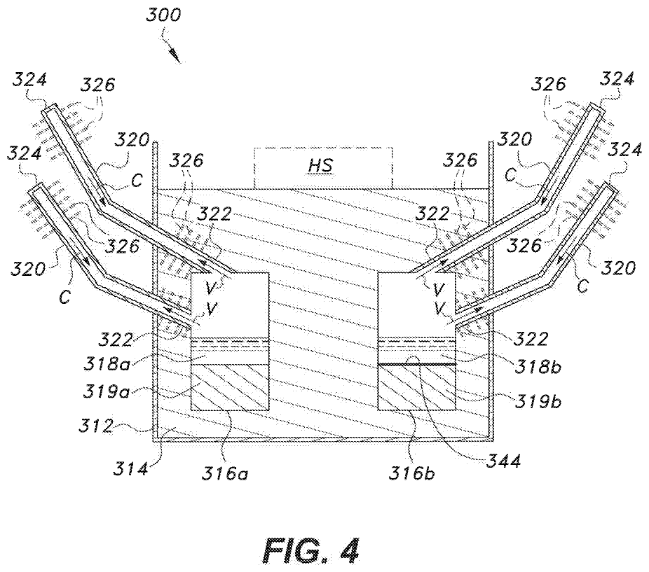

The heat sink with an internal chamber for a phase change material, designated generally as 300 in the alternative embodiment of FIG. 4, is similar to that of the previous embodiments, including a first body of a solid phase change material 314 disposed within a thermally conductive housing 312, the first body of solid phase change material 314 being adapted for direct contact with a heat source HS. As noted above with respect to the previous embodiments, a plurality of internal chambers may be formed within the first body of solid phase change material 314. In the example of FIG. 4, two such internal chambers 316a, 316b are provided, although it should be understood that any suitable number of internal chambers may be formed within the first body of solid phase change material 314. As in the previous embodiments, it should be understood that the overall configuration and relative dimensions of the housing 312, the first body of solid phase change material 314, and the internal chambers 316a, 316b are shown for purposes of illustration only.

Similar to the previous embodiments, a quantity of at least one liquid phase change material 318a, 318b at least partially fills each of the internal chambers 316a, 316b formed within the body of solid phase change material 314. However, in addition to the at least one liquid phase change material 318a, 318b, a second body of solid phase change material 319a, 319b can also be disposed within each of the internal chambers 316a, 316b.

The alternative embodiment of FIG. 4 includes a plurality of tubes 320 in communication with each of the internal chambers 316a, 316b. In the non-limiting example of FIG. 4, two such tubes 320 are provided for each of the internal chambers 316a, 316b. Each of the plurality of tubes 320 has a first end 322 in open fluid communication with the corresponding one of internal chambers 316a, 316b formed within the first body of solid phase change material 314, and an opposed second end 324. In the embodiment of FIG. 4, the second end 324 is again closed. As in the previous embodiments, each of the plurality of tubes 320 at least partially projects through and outside of the first body of solid phase change material 314 and the thermally conductive housing 312, and may have a plurality of thermally conductive fins 326 mounted on at least a portion thereof. The thermally conductive fins 326 may be mounted outside the body of the solid phase change material 314 and the thermally conductive housing 312, inside the body of the solid phase change material 314, or both. It should be understood that the overall configuration and relative dimensions of the plurality of tubes 320 are shown for exemplary purposes only. Similarly, it should be understood that the positioning, overall configuration, relative dimensions, and number of thermally conductive fins 326 are also shown for exemplary purposes only.

As in the previous embodiment, the at least one liquid phase change materials 318a, 318b are selected such that after forming a vapor V by exposure to heat from the heat source HS, the vapor V will condense back into a liquid when exposed, through the plurality of tubes 320, to the conditions of the ambient environment within which the heat sink will be operating. The selection of the at least one liquid phase change material 318a, 318b may depend upon a number of conditions, including anticipated pressure in each of the internal chambers 316a, 316b and external temperature during operation, and the surface area of the plurality of tubes 320. Under otherwise standard conditions, such as atmospheric temperature, the at least one liquid phase change material 318a, 318b will have a boiling point slightly above the temperature of the ambient environment. Where the plurality of tubes 320 have a larger surface area, the at least one liquid phase change material 318a, 318b will be selected to have a boiling point 1° to 5° C. above the temperature of the ambient environment. Where the plurality of tubes 320 have a smaller surface area, the at least one liquid phase change material 318a, 318b will be selected to have a boiling point 5° to 10° C. above the temperature of the ambient environment. Generally, the anticipated atmospheric temperature and the surface area of the plurality of tubes 320 will be the primary criteria used to select an appropriate at least one liquid phase change material 318a, 318b. Multiple liquid phase change materials 318a, 318b having different boiling points within the desired range of operation may be mixed in the internal chambers 316a, 316b in order to smooth the temperature range of phase change under varying ambient conditions. The pressure of the internal chambers 316a, 316b may also be adjusted to optimize the boiling point of the selected liquid phase change material for a particular intended use. Non-limiting examples of liquid phase change materials 318a, 318b include one or more of water, formic acid, caprylic acid, glycerin, acetic acid, polyethylene glycol 600, n-hexadecane and n-heptadecane. In one embodiment, the liquid phase change materials 318a, 318b are the same in each of the plurality of internal chambers 316a, 316b. In another embodiment, the liquid phase change materials 318a, 318b are different in one or more of the plurality of internal chambers 316a, 316b.

As in the previous embodiment, the phase change material for the first body of solid phase change material 314 is selected such that it has a melting temperature between the operating temperature of the heat sink and the boiling temperature of the at least one liquid phase change material 318a, 318b. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobcnzene, heptaudecanoic acid, beeswax, glyolic acid, glycolic acid, capric acid, eladic acid, and pentadecanoic acid.

The alternative embodiment of FIG. 4 includes at least one second body of solid phase change material 319a, 319b, disposed within the internal chambers 316a, 316b. The solid phase change material suitable for the second body of solid phase change material is selected such that it has a melting temperature between the highest boiling temperature of the at least one liquid phase change material 318a, 318b and the melting temperature of the first body of solid phase change material 314. Non-limiting examples of suitable solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

In the alternative embodiment of FIG. 4, the at least one liquid phase change material 318a, 318b and the at least one second body of solid phase change material 319a, 319b may be selected such that they are compatible. In the alternative, the at least one liquid phase change material 318a, 318b and the at least one second body of solid phase change material 319a, 319b may be selected based upon other criteria, and a partition 344 of conductive material may separate the at least one liquid phase change material 318a, 318b and the at least one second body of solid phase change material 319a, 319b. As illustrated in FIG. 4, the internal chamber 316b includes a partition 344 and the internal chamber 316a does not. However, it should be understood that any combination of internal chambers 316a, 316b including or excluding the partition 344 may be used, depending upon the at least one liquid phase change material 318a, 318b and the at least one second body of solid phase change material 319a, 319b that are selected in each internal chamber 316a, 316b.

In use of the embodiment of FIG. 4, heat generated by the heat source HS is transferred, via conduction, into the first body of solid phase change material 314. This may result in melting of at least a portion of the first body of solid phase change material 314, absorbing some of the heat from the heat source. In addition to the heat transferred into the first body of solid phase change material 314 and used in the melting thereof, the heat can further be transferred into the at least one second body of solid phase change material 319a, 319b within the internal chambers 316a, 316b, which may result in melting of at least a portion of the at least one second body of solid phase change material 319a, 319b, absorbing some of the heat from the heat source. Heat is also transferred from the first body of solid phase change material 314 and/or the at least one second body of solid phase change material 319a, 319b, to the at least one liquid phase change material 318a, 318b contained within the internal chambers 316a, 316b. The heat causes at least a portion of the at least one liquid phase change material 318 in the internal chambers 316a, 316b to evaporate, and the vapor V flows into the plurality of tubes 320. As described above, in the embodiment of FIG. 1, the second end 324 of the plurality of tubes 320 is closed. The vapor V cools through heat exchange with the ambient environment (enhanced by cooling fins 326). The cooling of the vapor V condenses the at least one liquid phase change material 318a, 318b back into its liquid state, and the at least one liquid phase change material 318a, 318b drips by gravity back into the internal chambers 316a, 316b for reuse. The use of a plurality of internal chambers 316a, 316b allows for more rapid heat capture and dissipation and ensures that the different areas of the heat sink 300 are cooled evenly, maintaining an almost uniform temperature across the heat sink 300. Thus the heat from the heat source HS is quickly and efficiently transferred to the ambient environment.

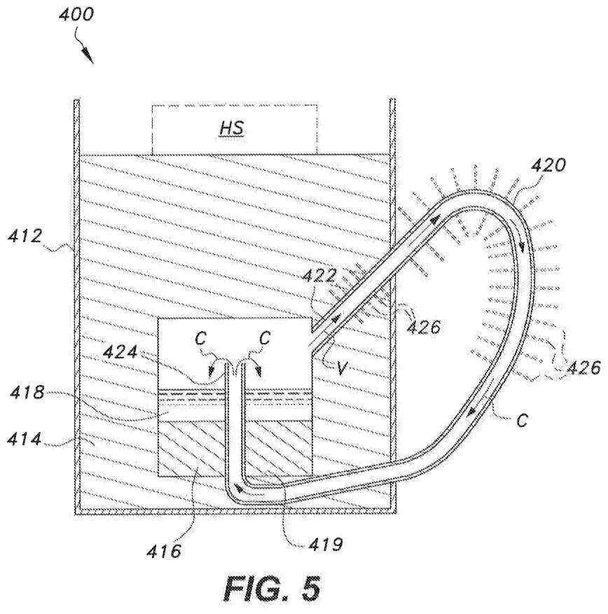

The heat sink with an internal chamber for a phase change material, designated generally as 400 in the alternative embodiment of FIG. 5, is similar to that of the previous embodiments, including a first body of solid phase change material 414 with at least one liquid phase change material 418 disposed in at least one internal chamber 416 defined therein. However, similar to the previous embodiment, a second body of solid phase change material 419 can also be disposed within the internal chamber 416. The first body of solid phase change material 414 is again disposed within a thermally conductive housing 412 and is adapted for direct contact with a heat source HS. As in the previous embodiments, it should be understood that the overall configuration and relative dimensions of the housing 412, the first body of solid phase change material 414, and the at least one internal chamber 416 are shown for purposes of illustration only.

Similar to the previous embodiments, a quantity of at least one liquid phase change material 418 at least partially fills at least one internal chamber 416 formed within the first body of solid phase change material 414.

The alternative embodiment of FIG. 5 includes at least one tube 420 having a first end 422 in open fluid communication with the at least one internal chamber 416 formed within the first body of solid phase change material 414, and an opposed second end 424. The opposed second end 424 is also in fluid communication with the at least one internal chamber 416, and particularly upon looping back through the first body of solid phase change material 414 and projecting back into the at least one internal chamber 416, the at least one tube 420 passes through the second body of solid phase change material 419 such that the second end 424 is positioned above the level of the at least one liquid phase change material 418. Thus, in use, as the at least one liquid phase change material 418 evaporates, the vapor V flows through the at least one tube 420 and condenses, the condensate C flowing back down the at least one tube 420 toward the open second end 424 by gravity, and thereby rejoining the at least one liquid phase material 418 in the at least one internal chamber 416, for reuse. In this embodiment the at least one tube 420 containing the condensate C passes through the first body of solid phase change material 414 and the second body of solid phase change material 419, providing additional opportunities for the condensate to absorb heat from the first body of solid phase change material 414 and the second body of solid phase change material 419. As in the previous embodiments, the at least one tube 420 at least partially projects through and outside of the first body of solid phase change material 414 and the thermally conductive housing 412, and may have a plurality of thermally conductive fins 426 mounted on at least a portion thereof. The thermally conductive fins 426 may be mounted outside the body of the solid phase change material 414 and the thermally conductive housing 412, inside the body of the solid phase change material 414, or both. In this alternative embodiment, the at least one tube 420 may have thermally conductive fins 426 mounted on the portion of the at least one tube 420 passing through the second body of solid phase change material 419, thereby increasing the surface area of the at least one tube 420 in contact with the second body of solid phase change material 419. It should be understood that the overall configuration and relative dimensions of the at least one tube 420 are shown for exemplary purposes only. Similarly, it should be understood that the positioning, overall configuration, relative dimensions, and number of thermally conductive fins 426 are also shown for exemplary purposes only.

As in the previous embodiment, the at least one liquid phase change material 418 is selected such that it will condense back into a liquid when exposed, through the at least one tube 420, to the conditions of the ambient environment within which the heat sink will be operating. The selection of the at least one liquid phase change material 418 may depend upon a number of conditions, including anticipated pressure in the at least one internal chamber 416 and external temperature during operation, and the surface area of the at least one tube. Under otherwise standard conditions, such as atmospheric temperature, the at least one liquid phase change material 418 will have a boiling point slightly above the temperature of the ambient environment. Where the at least one tube 420 has a larger surface area, the at least one liquid phase change material 418 will be selected to have a boiling point 1° to 5° C. above the temperature of the ambient environment. Where the at least one tube 420 has a smaller surface area, the at least one liquid phase change material 418 will be selected to have a boiling point 5° to 10° C. above the temperature of the ambient environment. Generally, the anticipated atmospheric temperature and the surface area of the at least one tube 420 will be the primary criteria used to select an appropriate at least one liquid phase change material 418. Multiple liquid phase change materials 418 having different boiling points within the desired range of operation may be mixed in the at least one internal chamber 416, in order to smooth the temperature range of phase change under varying ambient conditions. The pressure of the at least one internal chamber 416 may also be adjusted to optimize the boiling point of the selected liquid phase change material for a particular intended use. Non-limiting examples of liquid phase change materials include one or more of water, formic acid, caprylic acid, glycerin, acetic acid, polyethylene glycol 600, n-hexadecane and n-heptadecane.

As in the previous embodiment, the phase change material for the first body of solid phase change material 414 is selected such that it has a melting temperature between the operating temperature of the heat sink and the boiling temperature of the at least one liquid phase change material 418. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

As in the previous embodiment the phase change material for the second body of solid phase change material 419 is selected such that it has a melting temperature between the highest boiling temperature of the at least one liquid phase change material 418 and the melting temperature of the first body of solid phase change material 414. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

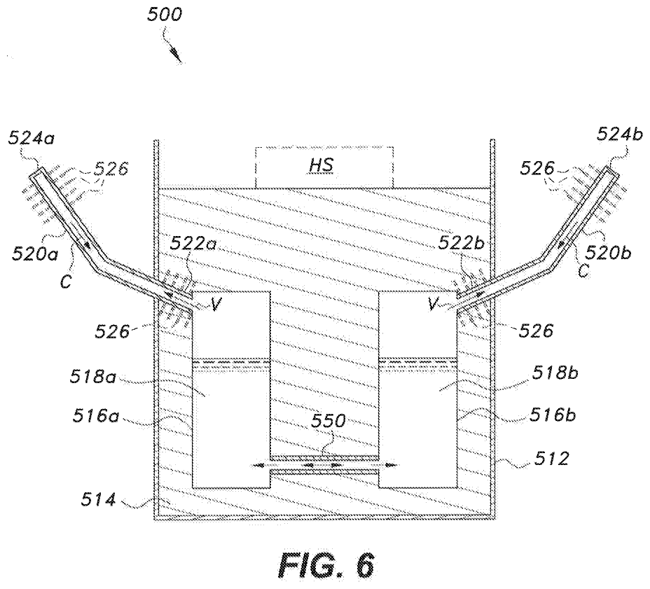

The alternative heat sink with internal chamber for a phase change material, designated generally as 500 in FIG. 6, is similar to the multi-chamber embodiment of FIG. 4, including a body of solid phase change material 514 disposed within a thermally conductive housing 512, the body of solid phase change material 514 being adapted for direct contact with a heat source HS. A plurality of internal chambers may be formed within the body of solid phase change material 514. In the example of FIG. 6, two such internal chambers 516a, 516b are provided, although it should be understood that any suitable number of internal chambers may be formed within the body of solid phase change material 514. As in the previous embodiments, it should be understood that the overall configuration and relative dimensions of the housing 512, the body of solid phase change material 514, and the internal chambers 516a, 516b are shown for purposes of illustration only.

The embodiment of FIG. 6 includes at least one tube 520a, 520b in respective communication with each of the internal chambers 516a, 516b. As shown in FIG. 6, the at least one tube 520a, 520b is respectively provided for each of the internal chambers formed within the body of solid phase change material 514. Each of the at least one tubes 520a, 520b has a respective first end 522a, 522b in open fluid communication with the corresponding one of the internal chambers 516a, 516b formed within the body of solid phase change material 514, and a respective opposed second end 524a, 524b. In the embodiment of FIG. 6, each second end 524a, 524b is closed. As in the previous embodiments, each of the at least one tubes 520a, 520b at least partially projects through and outside of the body of solid phase change material 514 and the thermally conductive housing 512. It should be understood that the overall configuration and relative dimensions of the at least one tubes 520a, 520b are shown for exemplary purposes only. Similar to the previous embodiments, a plurality of thermally conductive fins 526 may be mounted on the exterior of the at least one tubes 520a, 520b. The thermally conductive fins 526 may be mounted outside the body of the solid phase change material 514 and the thermally conductive housing 512, inside the body of the solid phase change material 514, or both.

Similar to the previous embodiments, a quantity of at least one liquid phase change material 518a, 518b at least partially fills each of the internal chambers 516a, 516b formed within the body of solid phase change material 514. As in the previous embodiment, the at least one liquid phase change material 518a, 518b is selected such that it will condense back into a liquid when exposed, through the at least one tubes 520a, 520b, to the conditions of the ambient environment within which the heat sink will be operating. The selection of the at least one liquid phase change material 518a, 518b may depend upon a number of conditions, including anticipated pressure in each of the internal chambers 516a, 516b and external temperature during operation, and the surface area of the at least one tubes 520a, 520b. Under otherwise standard conditions, such as atmospheric temperature, the at least one liquid phase change material 518a, 518b will have a boiling point slightly above the temperature of the ambient environment. Where the at least one tube 520a, 520b has a larger surface area, the at least one liquid phase change material 518a, 518b will be selected to have a boiling point 1° to 5° C. above the temperature of the ambient environment. Where the at least one tube 520a, 520b has a smaller surface area, the at least one liquid phase change material 518a, 518b will be selected to have a boiling point 5° to 10° C. above the temperature of the ambient environment. Generally, the anticipated atmospheric temperature and the surface area of the at least one tube 520a, 520b will be the primary criteria used to select an appropriate at least one liquid phase change material 518a, 518b. Multiple liquid phase change materials 518a, 518b having different boiling points within the desired range of operation may be mixed in the internal chambers 516a, 516b, in order to smooth the temperature range of phase change under varying ambient conditions. The pressure of the internal chambers 516a, 516b may also be adjusted to optimize the boiling point of the selected liquid phase change material for a particular intended use. Non-limiting examples of liquid phase change materials include one or more of water, formic acid, caprylic acid, glycerin, acetic acid, polyethylene glycol 600, n-hexadecane and n-heptadecane.

Similar to the previous embodiment, the phase change material for the body of solid phase change material 514 is selected such that it has a melting temperature between the operating temperature of the heat sink and the boiling temperature of the at least one liquid phase change material 518a, 518b. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

Further, as shown in FIG. 6, a fluid passage 550 may be formed through the body of solid phase change material 514 to connect the internal chambers 516a, 516b, such that the internal chambers 516a, 516b are in open fluid communication. Thus, the at least one liquid phase change material 518a, 518b is able to flow from one internal chamber 516a, 516b to another, maintaining a homogeneous temperature and composition of liquid phase change material 518a, 518b in the separate internal chambers 516a, 516b. The fluid passage 550 will thus ensure that a single internal chamber 516a, 516b, does not run out of the at least one liquid phase change material 518a, 518b, as long as reserves of the at least one liquid phase change material 518a, 518b are available in any of the internal chambers 516a, 516b. In one embodiment, the liquid phase change materials 518a, 518b are the same in each of the plurality of internal chambers 516a, 516b. In another embodiment particularly suited to cooling non-uniformly distributed heat sources, the liquid phase change materials 518a, 518b are different in one or more of the plurality of internal chambers 516a, 516b. When different liquid phase change materials 518a, 518b are used in this embodiment only internal chambers 516a, 516b having the same liquid phase change materials 518a, 518b are connected by the fluid passage 550.

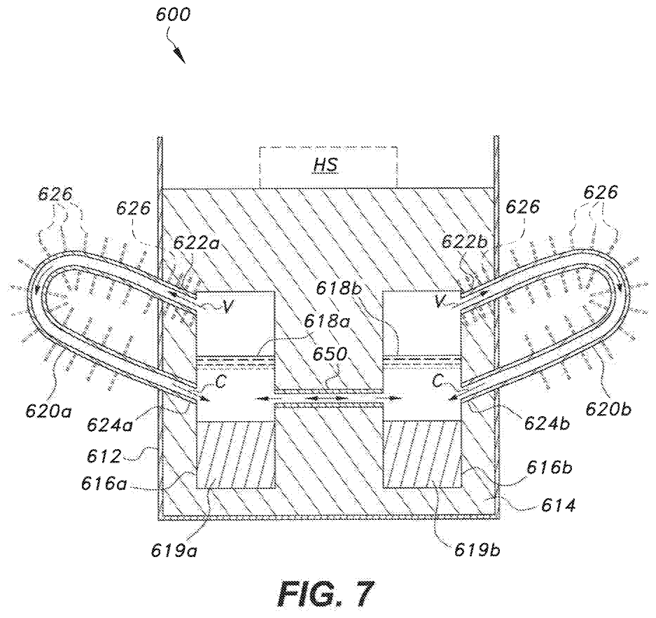

The alternative heat sink with an internal chamber for a phase change material, designated generally as 600 in FIG. 7, includes a first body of solid phase change material 614 disposed within a thermally conductive housing 612, the first body of solid phase change material 614 being adapted for direct contact with a heat source HS. A plurality of internal chambers may be formed within the first body of solid phase change material 614. In the example of FIG. 7, two such internal chambers 616a, 616b are provided, although it should be understood that any suitable number of internal chambers may be formed within the body of solid phase change material 614. As in the previous embodiments, it should be understood that the overall configuration and relative dimensions of the housing 612, the first body of solid phase change material 614, and the internal chambers 616a, 616b are shown for purposes of illustration only.

The embodiment of FIG. 7 includes at least one tube 620a, 620b in respective communication with each of the internal chambers 616a, 616b. At least one tube 620a, 620b is respectively provided for each of the internal chambers 616a, 616b formed within the first body of solid phase change material 614. Each of the at least one tubes 620a. 620b has a respective first end 622a, 622b in open fluid communication with the corresponding one of the internal chambers 616a, 616b formed within the first body of solid phase change material 614, and a respective opposed second end 624a, 624b. Similar to the embodiment of FIG. 3, each of the at least one tubes 620a, 620b is curved in order to loop back within the housing 612 and the first body of solid phase change material 614, each second end 624a, 624b feeding the phase change condensate back into the respective internal chamber 616a, 616b. As in the previous embodiments, each of the at least one tubes 620a, 620b at least partially projects through and outside of the body of solid phase change material 614 and the thermally conductive housing 612. Similar to the previous embodiments, a plurality of thermally conductive fins 626 may be mounted on the exterior of the at least one tubes 620a, 620b. The thermally conductive fins 626 may be mounted outside the body of the solid phase change material 614 and the thermally conductive housing 612, inside the body of the solid phase change material 614, or both. It should be understood that the overall configuration and relative dimensions of the at least one tubes 620a, 620b are shown for exemplary purposes only.

Similar to the previous embodiments, a quantity of at least one liquid phase change material 618a, 618b at least partially fills each of the internal chambers 616a, 616b formed within the first body of solid phase change material 614. However, in addition to the at least one liquid phase change material 618a, 618b, a second body of solid phase change material 619a, 619b can also be disposed within each of the internal chambers 616a, 616b.

As in previous embodiments, the at least one liquid phase change material 618a, 618b is selected such that it will vaporize when exposed to sufficient heat from the heat source HS, and condense back into a liquid when exposed, through the at least one tubes 620a, 620b, to the conditions of the ambient environment within which the heat sink will be operating. The selection of the at least one liquid phase change material 618a, 618b may depend upon a number of conditions, including anticipated pressure in each of the internal chambers 616a, 616b and external temperature during operation, and the surface area of the at least one tube 620a, 620b. Under otherwise standard conditions, such as atmospheric temperature, the at least one liquid phase change material 618a, 618b will have a boiling point slightly above the temperature of the ambient environment. Where the at least one tube 620a, 620b has a larger surface area, the at least one liquid phase change material 618a, 618b will be selected to have a boiling point 1° to 5° C. above the temperature of the ambient environment. Where the at least one tube 620a, 620b has a smaller surface area, the at least one liquid phase change material 618a, 618b will be selected to have a boiling point 5° to 10° C. above the temperature of the ambient environment. Generally, the anticipated atmospheric temperature and the surface area of the at least one tube 620a, 620b will be the primary criteria used to select an appropriate at least one liquid phase change material 618a, 618b. Multiple liquid phase change materials 618a, 618b having different boiling points within the desired range of operation may be mixed in the at least one internal chamber 616a, 616b, in order to smooth the temperature range of phase change under varying ambient conditions. The pressure of the at least one internal chambers 616a, 616b may also be adjusted to optimize the boiling point of the selected liquid phase change material for a particular intended use. Non-limiting examples of liquid phase change materials include one or more of water, formic acid, caprylic acid, glycerin, acetic acid, polyethylene glycol 600, n-hexadecane and n-heptadecane.

As in the previous embodiment, the solid phase change material for the first body of solid phase change material 614 is selected such that it has a melting temperature between the operating temperature of the heat sink and the boiling temperature of the at least one liquid phase change material 618a, 618b. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

As in previous embodiments the solid phase change material for the second body of solid phase change material 619a, 619b is selected such that it has a melting temperature between the highest boiling temperature of the at least one liquid phase change material 618a. 618b and the melting temperature of the first body of solid phase change material 614. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

Further, as shown in FIG. 7, similar to the embodiment of FIG. 6, a fluid passage 650 may be formed through the body of solid phase change material 614 to connect the internal chambers 616a, 616b, such that the internal chambers 616a, 616b are in open fluid communication. Thus, the at least one liquid phase change material 618a, 618b is able to flow from one internal chamber 616a, 616b to another, maintaining a homogeneous temperature and composition of the at least one liquid phase change material 618a, 618b in the separate internal chambers 616a, 616b. The fluid passage 650 will thus ensure that a single internal chamber 616a, 616b, does not run out of the at least one liquid phase change material 618a, 618b, as long as reserves of the at least one liquid phase change material 618a, 618b are available in any of the internal chambers 616a, 616b.

In one embodiment, the liquid phase change materials 618a, 618b are the same in each of the plurality of internal chambers 616a, 616b. In another embodiment, the liquid phase change materials 618a, 618b are different in one or more of the plurality of internal chambers 616a, 616b. In one embodiment, the solid phase change materials 619a, 619b are the same in each of the plurality of internal chambers 616a, 616b. In another embodiment particularly suited to cooling non-uniformly distributed heat sources, the solid phase change materials 619a, 619b are different in one or more of the plurality of internal chambers 616a, 616b. When different liquid phase change materials 618a, 618b are used in this embodiment only internal chambers 616a, 616b having the same liquid phase change materials 618a, 618b are connected by the fluid passage 650.

In use of the embodiment of FIG. 7, heat generated by the heat source HS is transferred, via conduction, into the first body of solid phase change material 614. This may result in melting of at least a portion of the first body of solid phase change material 614, absorbing some of the heat from the heat source. In addition to the heat transferred into the first body of solid phase change material 614 and used in the melting thereof, the heat can further be transferred into the at least one second body of solid phase change material 619a, 619b within the internal chambers 616a, 616b, which may result in melting of at least a portion of the at least one second body of solid phase change material 619a, 619b, absorbing some of the heat from the heat source. Heat is also transferred from the first body of solid phase change material 614 and/or the at least one second body of solid phase change material 619a, 619b, to the at least one liquid phase change material 618a, 618b contained within the internal chambers 616a, 616b. The heat causes some portion of the at least one liquid phase change material 618a, 618b in the internal chambers 616a, 616b to evaporate, and the vapor V flows into the at least one tube 620a, 620b. As described above, in the embodiment of FIG. 7, the second end 624a, 624b of the at least one tube 620a, 620b is in open fluid communication with the internal chambers 616a, 616b. The vapor V cools through heat exchange with the ambient environment (enhanced by optional cooling fins 626). The cooling of the vapor V condenses the at least one liquid phase change material 618 back into its liquid state, and the at least one liquid phase change material 618a, 618b drips by gravity back toward the second end 624a, 624b of the at least one tube 620a, 620b and rejoins the at least one liquid phase change material 618a, 618b in the plurality of internal chambers 616a, 616b for reuse. The use of a plurality of internal chambers 616a, 616b allows for more rapid heat capture and dissipation and ensures that the different areas of the heat sink 600 are cooled evenly, maintaining an almost uniform temperature across the heat sink 600. Thus the heat from the heat source HS is quickly and efficiently transferred to the ambient environment.

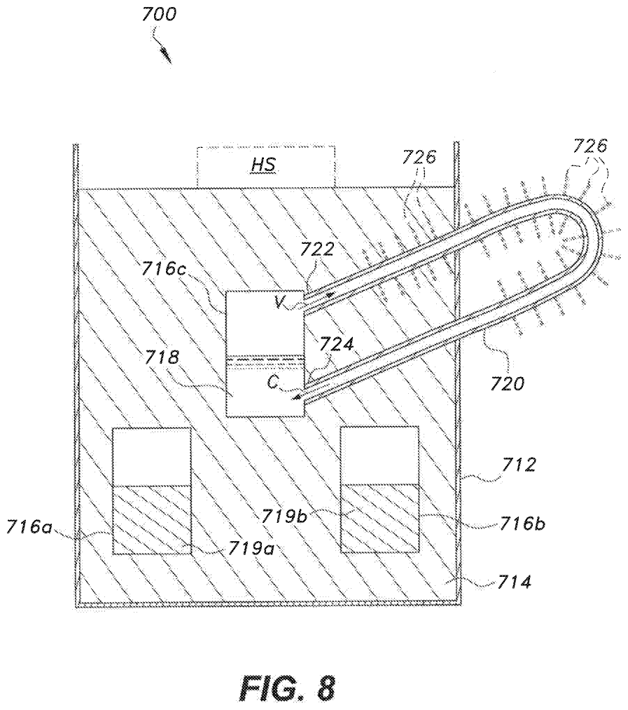

The heat sink with an internal chamber for a phase change material, designated generally as 700 in the alternative embodiment of FIG. 8, is similar to that of the embodiment of FIG. 1, including a first body of solid phase change material 714, and at least one liquid phase change material 718 disposed in at least one internal chamber 716c defined therein. The first body of solid phase change material 714 is disposed within a thermally conductive housing 712 and is adapted for direct contact with a heat source HS. As in the previous embodiments, it should be understood that the overall configuration and relative dimensions of the housing 712, the first body of solid phase change material 714, and the internal chamber 716c are shown for purposes of illustration only.

The alternative embodiment of FIG. 8 includes at least one tube 720 having a first end 722 in open fluid communication with the at least one internal chamber 716c formed within the first body of solid phase change material 714, and an opposed second end 724. Similar to the embodiment of FIG. 3, the opposed second end 724 is also in fluid communication with the at least one internal chamber 716c. As in the previous embodiments, the at least one tube 720 at least partially projects through and outside of the first body of solid phase change material 714 and the thermally conductive housing 712, and may have a plurality of thermally conductive fins 726 mounted on at least a portion thereof. The thermally conductive fins 726 may be mounted outside the body of the solid phase change material 714 and the thermally conductive housing 712, inside the body of the solid phase change material 714, or both. It should be understood that the overall configuration and relative dimensions of the at least one tube 720 are shown for exemplary purposes only. Similarly, it should be understood that the positioning, overall configuration, relative dimensions and number of thermally conductive fins 726 are also shown for exemplary purposes only.

Similar to the previous embodiments, a quantity of at least one liquid phase change material 718 at least partially fills at least one internal chamber 716c formed within the first body of solid phase change material 714. As shown, in addition to the at least one internal chamber 716c, a plurality of additional internal chambers 716a, 716b are also formed in the first body of solid phase change material 714. Each of the plurality of additional internal chambers 716a, 716b is at least partially filled with a second body of solid phase change material 719a, 719b. In an embodiment, the solid phase change material selected for the second body of solid phase change material 719a, 719b partially filling the internal chambers 716a, 716b may be the same solid phase change material. In an embodiment, the solid phase change material selected for the second body of solid phase change material 719a, 719b partially filling the plurality of additional internal chambers 716a, 716b may be different solid phase change materials.

As in previous embodiments, in use, as the at least one liquid phase change material 718 evaporates, the vapor V flows through the at least one tube 720 and condenses, the condensate C flowing back down the at least one tube 720 toward the open second end 724 by gravity and rejoining the at least one liquid phase change material 718 in the at least one internal chamber 716c for reuse. The at least one liquid phase change material 718 is selected such that it will condense back into a liquid when exposed, through the at least one tube 720, to the conditions of the ambient environment within which the heat sink will be operating. The selection of the at least one liquid phase change material 718 may depend upon a number of conditions, including anticipated pressure in the at least one internal chamber 716c, the external temperature during operation, and the surface area of the at least one tube 720. Under otherwise standard conditions, such as atmospheric temperature, the at least one liquid phase change material 718 will have a boiling point slightly above the temperature of the ambient environment. Where the at least one tube 720 has a larger surface area, the at least one liquid phase change material 718 will be selected to have a boiling point 1° to 5° C. above the temperature of the ambient environment. Where the at least one tube 720 has a smaller surface area, the at least one liquid phase change material 718 will be selected to have a boiling point 5° to 10° C. above the temperature of the ambient environment. Generally, the anticipated atmospheric temperature and the surface area of the at least one tube 720 will be the primary criteria used to select an appropriate at least one liquid phase change material 718. Multiple liquid phase change materials 718 having different boiling points within the desired range of operation may be mixed in the at least one internal chamber 716c, in order to smooth the temperature range of phase change under varying ambient conditions. The pressure of the at least one internal chamber 716c may also be adjusted to optimize the boiling point of the selected liquid phase change material for a particular intended use. Non-limiting examples of liquid phase change materials include one or more of water, formic acid, caprylic acid, glycerin, acetic acid, polyethylene glycol 600, n-hexadecane and n-heptadecane.

As in previous embodiments, the phase change material for the first body of solid phase change material 714 is selected such that it has a melting temperature between the operating temperature of the heat sink and the boiling temperature of the at least one liquid phase change material 718. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

As in the embodiment of FIG. 4, the phase change material for the second body of solid phase change material 719a, 719b is selected such that it has a melting temperature between the highest boiling temperature of the at least one liquid phase change material 718 and the melting temperature of the first body of solid phase change material 714. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

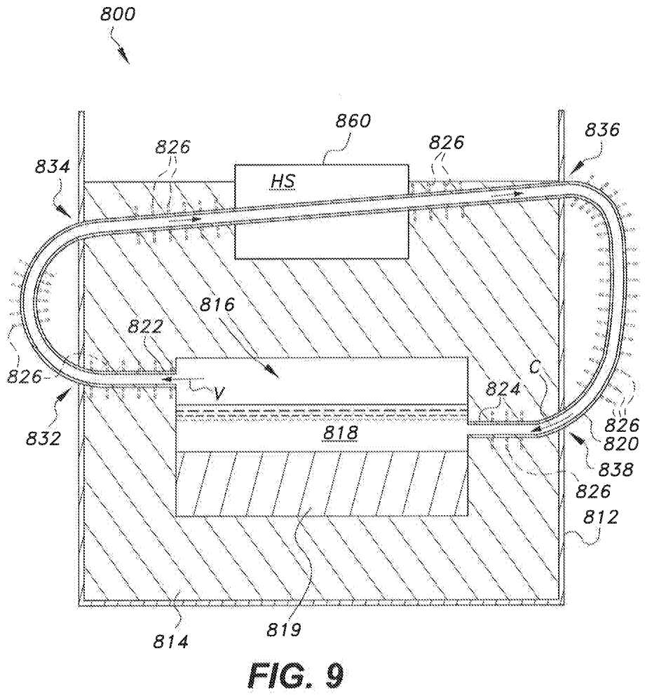

In the further embodiment of FIG. 9, the heat sink with an internal chamber for a phase change material, designated generally as 800, includes a first body of solid phase change material 814 and at least one liquid phase change material 818 disposed in an internal chamber 816 defined therein. The first body of solid phase change material 814 is disposed within a thermally conductive housing 812 and is adapted for direct contact with a heat source, which may be, e.g., an electronics module 860 that may be at least partially embedded within the first body of solid phase change material 814. As in the previous embodiments, it should be understood that the overall configuration and relative dimensions of the housing 812, the first body of solid phase change material 814, and the internal chamber 816 are shown for purposes of illustration only.

Similar to the previous embodiments, a quantity of at least one liquid phase change material 818 at least partially fills the at least one internal chamber 816 formed within the first body of solid phase change material 814. In the alternative embodiment of FIG. 9, a quantity of a second body of solid phase change material 819 at least partially fills the at least one internal chamber 816.

The alternative embodiment of FIG. 9 includes at least one tube 820 having a first end 822 in open fluid communication with the at least one internal chamber 816 formed within a first body of solid phase change material 814, and an opposed second end 824. Similar to the embodiment of FIG. 3, the opposed second end 824 is also in fluid communication with the at least one internal chamber 816. However, in the orientation of FIG. 9, the at least one tube 820 exits the housing 812 through opening 832 and re-enters the first body of solid phase change material 814 through an adjacent opening 834, thus exposing a portion of the at least one tube 820 on its left side to the ambient environment. The at least one tube 820 then rises towards module 860 and passes through a passage formed through module 860, providing additional cooling via heat transfer for module 860, and then exits the housing 812 again, through opening 836. The at least one tube 820 then re-enters the first body of solid phase change material 814 through adjacent opening 838, before returning to the internal chamber 816, through the open connection of second end 824 with the internal chamber 816. As in the previous embodiments, the at least one tube 820 may have a plurality of thermally conductive fins 826 mounted on at least a portion thereof. The thermally conductive fins 826 may be mounted outside the body of the solid phase change material 814 and the thermally conductive housing 812, inside the body of the solid phase change material 814, or both. It should be understood that the overall configuration and relative dimensions of the at least one tube 820 are shown for exemplary purposes only. Similarly, it should be understood that the positioning, overall configuration, relative dimensions, and number of thermally conductive fins 826 are also shown for exemplary purposes only.

As in previous embodiments, the at least one liquid phase change material 818 is selected such that it will condense back into a liquid when exposed, through the at least one tube 820, to the conditions of the ambient environment within which the heat sink will be operating. The selection of the at least one liquid phase change material 818 may depend upon a number of conditions, including anticipated pressure in the at least one internal chamber 816 and external temperature during operation, and the surface area of the at least one tube 820. Under otherwise standard conditions, such as atmospheric temperature, the at least one liquid phase change material 818 will have a boiling point slightly above the temperature of the ambient environment. Where the at least one tube 820 has a larger surface area, the at least one liquid phase change material 818 will be selected to have a boiling point 1° to 5° C. above the temperature of the ambient environment. Where the at least one tube 820 has a smaller surface area, the at least one liquid phase change material 818 will be selected to have a boiling point 5° to 10° C. above the temperature of the ambient environment. Generally, the anticipated atmospheric temperature and the surface area of the at least one tube 820 will be the primary criteria used to select an appropriate at least one liquid phase change material 818. Multiple liquid phase change materials 818 having different boiling points within the desired range of operation may be mixed in the at least one internal chamber 816, in order to smooth the temperature range of phase change under varying ambient conditions. The pressure of the at least one internal chamber 816 may also be adjusted to optimize the boiling point of the selected liquid phase change material for a particular intended use. Non-limiting examples of liquid phase change materials include one or more of water, formic acid, caprylic acid, glycerin, acetic acid, polyethylene glycol 600, n-hexadecane and n-heptadecane.

As in previous embodiments, the phase change material for the first body of solid phase change material 814 is selected such that it has a melting temperature between the operating temperature of the heat sink and the boiling temperature of the at least one liquid phase change material 818. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

As in the previous embodiment, the phase change material for the second body of solid phase change material 819 is selected such that it has a melting temperature between the highest boiling temperature of the at least one liquid phase change material 818 and the melting temperature of the first body of solid phase change material 814. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

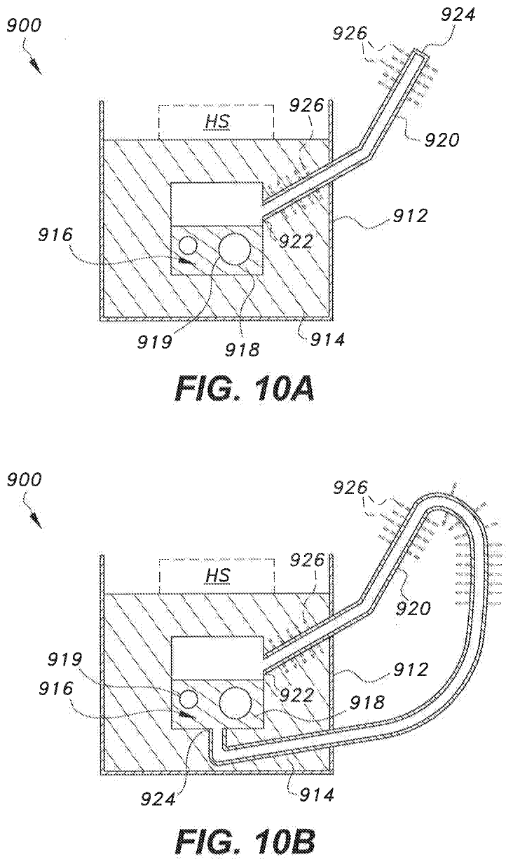

The heat sink with an internal chamber for a phase change material, designated generally as 900 in FIGS. 10A and 10B, is similar to the embodiment of FIG. 1, including a body of solid phase change material 914 disposed within a thermally conductive housing 912 such that at least one contact face of the body of solid phase change material 914 is exposed, allowing for direct contact with a heat source HS for cooling the heat source HS. It should be understood that the overall configuration and relative dimensions of the housing 912, the body of solid phase change material 914, and the at least one internal chamber 916, which is formed within the body of solid phase change material 914, are shown for purposes of illustration only.

A quantity of at least one liquid phase change material 918 at least partially fills the at least one chamber 916 formed within the body of solid phase change material 914. Although only a single internal chamber 916 is shown in the example of FIGS. 10A and 10B, it should be understood that a plurality of internal chambers 916 may be formed within the body of solid phase change material 914.

The first end 922 of at least one tube 920 is in open fluid communication with the at least one internal chamber 916 formed within the body of solid phase change material 914. In the example of FIGS. 10A and 10B, only one such at least one tube 920 is shown. However, it should be understood that a plurality of such at least one tubes 920 may be provided. The at least one tube 920 at least partially projects through and outside of the body of solid phase change material 914 and the thermally conductive housing 912. In the embodiment of FIG. 10A, the second end 924 of the at least one tube 920, which is opposed to first end 922, is closed. In the embodiment of FIG. 10B, the at least one tube 920 returns through the thermally conductive housing 912 and the body of solid phase change material 914, and the second end 924 of the at least one tube 920 is in open fluid communication with the at least one internal chamber 916. In the alternative embodiment of FIG. 10B, the second end 924 of the at least one tube 920 is in open fluid communication with the lower portion of the at least one internal chamber 916. It should be understood that the overall configuration and relative dimensions of the at least one tube 920 are shown for exemplary purposes only. Similar to the previous embodiments, a plurality of thermally conductive fins 926 may be mounted on the exterior of the at least one tube 920. The thermally conductive fins 926 may be mounted outside the body of the solid phase change material 914 and the thermally conductive housing 912, inside the body of the solid phase change material 914, or both. It should be understood that the positioning, overall configuration, relative dimensions, and number of thermally conductive fins 926 are shown for exemplary purposes only.

In the alternative embodiment of FIGS. 10A and 10B, the heat sink with an internal chamber for phase change material includes grains or particles of at least one encapsulated phase change material 919, within the at least one internal chamber 916 formed within the body of solid phase change material 914. The at least one encapsulated phase change material 919 may be a liquid phase change material or a solid phase change material.

As in previous embodiments, the at least one liquid phase change material 918 is selected such that after forming a vapor V by exposure to heat from the heat source HS, the vapor V will condense back into a liquid when exposed, through the at least one tube 920, to the conditions of the ambient environment within which the heat sink will be operating. In the alternative embodiment of FIG. 10B, the return of the condensate through the second end 924 of the at least one tube 920 will agitate the at least one liquid phase change material 918 and the at least one encapsulated phase change material 919, further increasing the heat transfer between the at least one liquid phase change material 918 and the at least one encapsulated phase change material 919. The selection of the at least one liquid phase change material 918 may depend upon a number of conditions, including anticipated pressure in the at least one internal chamber 916 and external temperature during operation, and the surface area of the at least one tube. Under otherwise standard conditions, such as atmospheric temperature, the at least one liquid phase change material 918 will have a boiling point slightly above the temperature of the ambient environment. Where the at least one tube 920 has a larger surface area, the at least one liquid phase change material 918 will be selected to have a boiling point 1° to 5° C. above the temperature of the ambient environment. Where the at least one tube 920 has a smaller surface area, the at least one liquid phase change material 918 will be selected to have a boiling point 5° to 10° C. above the temperature of the ambient environment. Generally, the anticipated atmospheric temperature and the surface area of the at least one tube 920 will be the primary criteria used to select an appropriate at least one liquid phase change material 918. Multiple liquid phase change materials 918 having different boiling points within the desired range of operation may be mixed in the at least one internal chamber 916, in order to smooth the temperature range of phase change under varying ambient conditions. The pressure of the at least one internal chamber 916 may also be adjusted to optimize the boiling point of the selected liquid phase change material for a particular intended use. Non-limiting examples of liquid phase change materials include one or more of water, formic acid, caprylic acid, glycerin, acetic acid, polyethylene glycol 600, n-hexadecane and n-heptadecane.

As in previous embodiments, the phase change material for the body of solid phase change material 914 is selected such that it has a melting temperature between the operating temperature of the heat sink and the boiling temperature of the at least one liquid phase change material 918. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

In the alternative embodiment of FIGS. 10A and 10B, the encapsulated phase change material 919 is selected such that it has a melting temperature between the highest boiling temperature of the at least one liquid phase change material 918 and the melting temperature of the body of solid phase change material 914. Non-limiting examples of liquid phase change materials useful as encapsulated phase change material 919 include one or more of water, formic acid, caprylic acid, glycerin, acetic acid, polyethylene glycol 600, n-hexadecane and n-heptadecane. Non-limiting examples of solid phase change materials useful as encapsulated phase change material 919 include one or more of elemental gallium, paraffin with between eighteen and thirty carbons, sodium sulfate, lauric acid, trimethylolethane, p-lattic acid, methyl palmitate, camphenilone, caprylone, heptadecanone, l-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

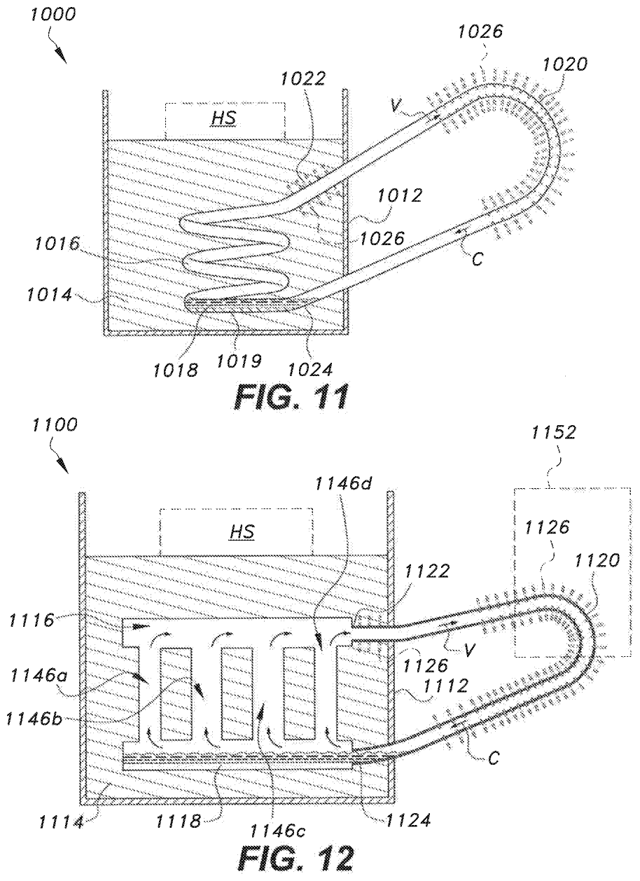

In the alternative embodiment of FIG. 11, the heat sink with internal chamber for phase change material, designated generally as 1000, is also a heat sink formed from a first body of solid phase change material 1014, with at least one liquid phase change material 1018 disposed in at least one internal chamber 1016 defined within the first body of solid phase change material 1014. However, similar to some previous embodiments, a second body of solid phase change material 1019 can also be disposed within the internal chamber 1016. The first body of solid phase change material 1014 is again disposed within a thermally conductive housing 1012 and is adapted for direct contact with a heat source HS. As in the previous embodiments, it should be understood that the relative dimensions of the housing 1012, the first body of solid phase change material 1014, the second body of solid phase change material 1019, and the at least one internal chamber 1016 are shown for purposes of illustration only.

A quantity of at least one liquid phase change material 1018 at least partially fills at least one internal chamber 1016 formed within the body of solid phase change material 1014. In the embodiment of FIG. 11, the at least one internal chamber 1016 forms a helical structure within the body of solid phase change material 1014.

In the embodiment of FIG. 11, a single tube 1020 is provided for each at least one internal chamber 1016. As in the embodiment of FIG. 3, the tube 1020 has a first end 1022 in open fluid communication with the at least one internal chamber 1016 formed within the body of solid phase change material 1014, and an opposed second end 1024 in open fluid communication with the at least one internal chamber 1016. Thus, in use, as the at least one liquid phase change material 1018 evaporates, the vapor V flows through the tube 1020 and condenses, the condensate C flowing back down by gravity to exit the tube 1020 through the open second end 1024 and back into the internal chamber 1016 for reuse. In the embodiment of FIG. 11, the helical structure of the at least one internal chamber 1016 causes additional swirling motion of the at least one liquid phase change material 1018 as it travels through the at least one internal chamber 1016, thereby increasing convective heat transfer to and from the at least one liquid phase change material 1018. As in the previous embodiments, the tube 1020 at least partially projects through and outside of the body of solid phase change material 1014 and the thermally conductive housing 1012, and may have a plurality of thermally conductive fins 1026 mounted on at least a portion thereof. The thermally conductive fins 1026 may be mounted outside the first body of the solid phase change material 1014 and the thermally conductive housing 1012, inside the first body of the solid phase change material 1014, or both. It should be understood that the overall configuration and relative dimensions of the tube 1020 are shown for exemplary purposes only. Similarly, it should be understood that the positioning, overall configuration, relative dimensions and number of thermally conductive fins 1026 are also shown for exemplary purposes only.

As in the previous embodiment, the at least one liquid phase change material 1018 is selected such that it will condense back into a liquid when exposed, through the tube 1020, to the conditions of the ambient environment within which the heat sink will be operating. The selection of the at least one liquid phase change material 1018 may depend upon a number of conditions, including anticipated pressure in the at least one internal chamber 1016 and external temperature during operation, and the surface area of the tube 1020. Under otherwise standard conditions, such as atmospheric temperature, the at least one liquid phase change material 1018 will have a boiling point slightly above the temperature of the ambient environment. Where the tube 1020 has a larger surface area, the at least one liquid phase change material 1018 will be selected to have a boiling point 1° to 5° C. above the temperature of the ambient environment. Where the tube 1020 has a smaller surface area, the at least one liquid phase change material 1018 will be selected to have a boiling point 5° to 10° C. above the temperature of the ambient environment. Generally, the anticipated atmospheric temperature and the surface area of the at least one tube 1020 will be the primary criteria used to select an appropriate at least one liquid phase change material 1018. Multiple liquid phase change materials 1018 having different boiling points within the desired range of operation may be mixed in the at least one internal chamber 1016 in order to smooth the temperature range of phase change under varying ambient conditions. The pressure of the at least one internal chamber 1016 may also be adjusted to optimize the boiling point of the selected liquid phase change material for a particular intended use. Non-limiting examples of liquid phase change materials 1018 include one or more of water, formic acid, caprylic acid, glycerin, acetic acid, polyethylene glycol 600, n-hexadecane and n-heptadecane.

As in the previous embodiments, the phase change material for the first body of solid phase change material 1014 is selected such that it has a melting temperature between the operating temperature of the heat sink and the boiling temperature of the at least one liquid phase change material 1018. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

As in some previous embodiments, the phase change material for the second body of solid phase change material 1019 is selected such that it has a melting temperature between the highest boiling temperature of the at least one liquid phase change material 1018 and the melting temperature of the first body of solid phase change material 1014. Non-limiting examples of suitable solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

In the alternative embodiment of FIG. 12, the heat sink with internal chamber for phase change material, designated generally as 1100, is also a heat sink formed from a body of solid phase change material 1114 with at least one liquid phase change material 1118 disposed in at least one internal chamber 1116 defined within the body of solid phase change material 1114. The body of solid phase change material 1114 is again disposed within a thermally conductive housing 1112 and is adapted for direct contact with a heat source HS. As in the previous embodiments, it should be understood that the relative dimensions of the housing 1112, the body of solid phase change material 1114, and the at least one internal chamber 1116 are shown for purposes of illustration only.

A quantity of at least one liquid phase change material 1118 at least partially fills the at least one internal chamber 1116 formed within the body of solid phase change material 1114. In the embodiment of FIG. 12, the at least one internal chamber 1116 within the body of solid phase change material 1014 includes a plurality of sub-chambers 1146a, 1146b, 1146c, 1146d in open fluid communication; however, it should be understood that any number of sub-chambers may be used. The plurality of sub-chambers 11146a, 1146b, 1146c, 1146d increases the surface area of the at least one internal chamber 1116, and thereby facilitates improved heat transfer from the body of solid phase change material 1114 to the at least one liquid phase change material 1018. Further, in the embodiment of FIG. 12, a single tube 1120 is provided for each at least one internal chamber 1116. As in the embodiment of FIG. 3, the tube 1120 has a first end 1122 in open fluid communication with the at least one internal chamber 1116 formed within the body of solid phase change material 1114, and an opposed second end 1124 in open fluid communication with the at least one internal chamber 1116. Thus, in use, as the at least one liquid phase change material 1118 evaporates, the vapor V flows through tube 1120 and condenses, the condensate C flowing back down by gravity to exit the tube 1120 through the open second end 1124 and back into the at least one internal chamber 1116 for reuse. As in the previous embodiments, the tube 1120 at least partially projects through and outside of the body of solid phase change material 1114 and the thermally conductive housing 1112, and may have a plurality of thermally conductive fins 1126 mounted on at least a portion thereof. The thermally conductive fins 1126 may be mounted outside the body of the solid phase change material 1114 and the thermally conductive housing 1112, inside the body of the solid phase change material 1114, or both. It should be understood that the overall configuration and relative dimensions of the tube 1120 are shown for exemplary purposes only. Similarly, it should be understood that the positioning, overall configuration, relative dimensions and number of thermally conductive fins 1126 are also shown for exemplary purposes only.

As in the previous embodiment, the at least one liquid phase change material 1118 is selected such that it will condense back into a liquid when exposed, through the tube 1120, to the conditions of the ambient environment within which the heat sink will be operating. The selection of the at least one liquid phase change material 1118 may depend upon a number of conditions, including anticipated pressure in the at least one internal chamber 1116 and external temperature during operation, and the surface area of the tube 1120. Under otherwise standard conditions, such as atmospheric temperature, the at least one liquid phase change material 1118 will have a boiling point slightly above the temperature of the ambient environment. Where the tube 1120 has a larger surface area, the at least one liquid phase change material 1118 will be selected to have a boiling point 1° to 5° C. above the temperature of the ambient environment. Where the tube 1120 has a smaller surface area, the at least one liquid phase change material 1118 will be selected to have a boiling point 5° to 10° C. above the temperature of the ambient environment. Generally, the anticipated atmospheric temperature and the surface area of the tube 1120 will be the primary criteria used to select an appropriate at least one liquid phase change material 1118. Multiple liquid phase change materials 1118 having different boiling points within the desired range of operation may be mixed in the at least one internal chamber 1116 in order to smooth the temperature range of phase change under varying ambient conditions. The pressure of the at least one internal chamber 1116 may also be adjusted to optimize the boiling point of the selected liquid phase change material for a particular intended use. Non-limiting examples of liquid phase change materials 1118 include one or more of water, formic acid, caprylic acid, glycerin, acetic acid, polyethylene glycol 600, n-hexadecane and n-heptadecane.

As in the previous embodiment, the phase change material for the body of solid phase change material 1114 is selected such that it has a melting temperature between the operating temperature of the heat sink and the boiling temperature of the at least one liquid phase change material 1118. Non-limiting examples of solid phase change materials include one or more of elemental gallium, paraffin with between eighteen and thirty carbons, sodium sulfate, lauric acid, trimethylolethane, p-lattic acid, methyl palmitate, camphenilone, caprylone, heptadecanone, 1-cyclohexyloctadecane, 4-heptadecanone, 3-heptadecanone, 2-heptadecanone, 9-heptadecanone, camphene, thymol, p-dichlorobenzene, heptaudecanoic acid, beeswax, glyolic acid, glycolic acid, capric acid, eladic acid, and pentadecanoic acid.

In an alternative embodiment, the embodiment of FIG. 12 may be adapted for use in a power station. In this embodiment, the tube 1120 carries the vapor V through the turbine and condenser of the power station 1152 and returns the condensate C to the at least one internal chamber 1116. In this embodiment, the first body of solid phase change material 1114 may be gallium and the at least one liquid phase change material 1118 may be water. In use, the first body of solid phase change material 1114 will generally be entirely in a liquid state. This alternative embodiment of FIG. 12 may be particularly suited at applications where the heat source HS is a concentrating solar collector, tubes carrying hot gases (such as those heated by combustion), tubes carrying hot fluids, and the like.

Features of each of the disclosed embodiments may be used in other of the disclosed embodiments. For example, the return tube of the embodiment of FIG. 5 can be used in the embodiment of FIG. 7, and so on.

In each of the disclosed embodiments, where the tube re-enters the body of solid phase change material, the track followed by the tube may be irregular, rather than direct. This increased the surface area of the tube carrying the cooler, condensed liquid phase change material, which is exposed to body of solid phase change material and thereby increase the capacity for further heat exchange to occur. In these embodiments, the diameter of the tube passing through the body of solid phase change material is preferably as small as possible. As discussed previously, a plurality of fins may be attached to the external surface of this portion of the tube.

It is to be understood that the heat sink with internal chamber for phase change material is not limited to the specific embodiments described above, but encompasses any and all embodiments within the scope of the generic language of the following claims enabled by the embodiments described herein, or otherwise shown in the drawings or described above in terms sufficient to enable one of ordinary skill in the art to make and use the claimed subject matter.

1. A heat sink with internal chamber for phase change material, comprising:
a thermally conductive housing;
a body of a first phase change material disposed within the thermally conductive housing, the body of the first phase change material having at least one contact face adapted for direct contact with a heat source to be cooled, the body of the first phase change material having a plurality of spaced apart internal chambers defined therein, wherein the plurality of internal chambers are distinct from the body of the first phase change material;
each of the internal chambers including a quantity of a first liquid phase change material at least partially filling a respective one of the internal chambers defined within the body of the first phase change material;
a plurality of tubes, each of the tubes having opposed first and second ends, the first end being in open fluid and thermal communication with a respective one of the internal chambers and being adapted to capture the vapors of the first liquid phase change material as it evaporates within its respective internal chamber and escapes to the open first end, wherein each of the second ends of the tubes at least partially projecting through and outside of the body of the first phase change material and the thermally conductive housing; and
a fluid passage formed through the body of the first phase change material and fluidically connecting the plurality of spaced apart internal chambers.

2. The heat sink as recited in claim 1, wherein the second end of the at least one tube is closed and is positioned outside of the body of the first phase change material and the thermally conductive housing.

3. The heat sink as recited in claim 1, further comprising a plurality of thermally conductive fins mounted on at least a portion of the at least one tube outside of the body of the first phase change material and the thermally conductive housing.

4-8. (canceled)

9. The heat sink as recited in claim 1, further comprising a quantity of a first solid phase change material disposed within at least one of the plurality of internal chambers.

10. The heat sink as recited in claim 9, further comprising a partition in the at least one of the plurality of internal chambers, the partition being fluid impermeable and separating the first solid phase change material from the first liquid phase change material.

11. (canceled)

12. The heat sink as recited in claim 9, wherein at least one of the plurality of tubes is configured to re-enter the body of the first phase change material and the thermally conductive housing and locate its second end within at least one of the plurality of internal chambers.

13. The heat sink as recited in claim 1, further comprising a quantity of an encapsulated phase change material disposed within at least one of the plurality of internal chambers.

14. (canceled)

15. The heat sink as recited in claim 1, wherein the second end of each of the plurality of tubes is closed and is positioned outside of the body of the first phase change material and the thermally conductive housing.

16-18. (canceled)

19. The heat sink as recited in claim 1, wherein each of the plurality of tubes is angularly oriented relative to their respective internal chamber.

20. The heat sink as recited in claim 1, wherein each of the second ends of the plurality of tubes is configured to loop back and re-enter its respective internal chamber.

21. A heat sink with internal chamber for phase change material, comprising:
a thermally conductive housing;
a body of a first phase change material disposed within the thermally conductive housing, the body of the first phase change material having at least one contact face adapted for direct contact with a heat source to be cooled, the body of the first phase change material having a plurality of spaced apart internal chambers defined therein, wherein the plurality of internal chambers are distinct from the body of the first phase change material;
each of the internal chambers having an upper portion and a bottom portion and comprises:
i) a quantity of a first liquid phase change material at least partially filling a respective one of the internal chambers defined within the body of the first phase change material; and
ii) a quantity of a first solid phase change material at least partially filling a respective one of the internal chambers defined within the body of the first phase change material; and
a plurality of tubes, each of the tubes having opposed first and second ends, the first end being in open fluid and thermal communication with a respective one of the internal chambers and being adapted to capture the vapors of the first liquid phase change material as it evaporates within its respective internal chamber and escapes to the open first end, wherein each of the second ends of the tubes at least partially projecting through and outside of the body of the first phase change material and the thermally conductive housing.

22. The heat sink as recited in claim 21, further comprising a partition in at least one of the plurality of internal chambers, the partition being fluid impermeable and separating the first solid phase change material from the first liquid phase change material.

23. The heat sink as recited in claim 21, further comprising a fluid passage formed through the body of the first phase change material and fluidically connecting the plurality of spaced apart internal chambers.

24. The heat sink as recited in claim 21, wherein at least one of the plurality of tubes is configured to re-enter the body of the first phase change material and the thermally conductive housing and to transit the body of the first phase change and locate its second end within one of the plurality of internal chambers.

25. The heat sink as recited in claim 24, wherein the second end of the at least one of the plurality of tubes is configured to re-enter the internal chamber at its bottom portion.

26. In combination, a heat source to be cooled and a heat sink with internal chamber for phase change material, comprising:
a thermally conductive housing;
a body of a first phase change material disposed within the thermally conductive housing, the body of the first phase change material having at least one contact face for contact with the heat source to be cooled, the body of the first phase change material having at least one internal chamber disposed therein;
the at least one internal chamber including:
i) a quantity of a first liquid phase change material at least partially filling the at least one of internal chamber; and
ii) a quantity of a first solid phase change material at least partially filling the at least one of internal chamber; and
at least one tube having opposed first and second ends, the first end being in open fluid and thermal communication with the at least one internal chamber and being adapted to capture the vapors of the first liquid phase change material as it evaporates within the at least one internal chamber and escapes to the open first end, wherein the at least one tube is configured to project through and outside the body of the first phase change material and the thermally conductive housing, re-enter the body of the first phase change material and the thermally conductive housing thereby transiting the body of the first phase change, passage through the heat source, project through and outside the body of the first phase change material and the thermally conductive housing, re-enter the body of the first phase change material and the thermally conductive housing, transit through the body of the first phase change and locate the second end of the at least one tube within the at least one first internal chamber.

27. The combination of a heat source and heat sink as recited in claim 26, further comprising a plurality of thermally conductive fins mounted on at least a portion of the at least one tube outside of the body of the first phase change material and the thermally conductive housing.

28. The combination of a heat source and heat sink as recited in claim 27, wherein the plurality of thermally conductive fins are mounted on the at least one tube inside of the body of the first phase change material and the thermally conductive housing.
